(19) United States
(12) Patent Application Publication
(10) Pub. No.: US 2025/0279715 A1
(43) Pub. Date: Sep. 4, 2025

(54) DEVICE AND METHOD FOR REDUCING OVERSHOOT VOLTAGE

(71) Applicant: SAMSUNG ELECTRONICS CO., LTD., SUWON-SI (KR)

(72) Inventors: Donghee CHO, Suwon-si (KR); Taesung KIM, Suwon-si (KR); Sangcheol MOON, Suwon-si (KR); Bonggeun CHUNG, Suwon-si (KR)

(21) Appl. No.: 18/975,019

(22) Filed: Dec. 10, 2024

(30) Foreign Application Priority Data
Mar. 4, 2024 (KR) 10-2024-0030912

(51) Int. Cl. H02M 1/32; G01R 19/00; H02M 1/088

(52) U.S. Cl. CPC H02M 1/32; G01R 19/0007; H02M 1/088

(57) ABSTRACT

A device and a method of sensing and compensating an overshoot voltage are disclosed. The device includes a power converter and an overshoot voltage compensation circuit. The overshoot voltage compensation circuit includes an overshoot voltage sensing circuit to generate a first comparison voltage by performing a filtering operation on the output voltage, and an overshoot voltage control circuit to generate a first control signal for controlling the operation of a power transistor based on the first comparison voltage. The first control signal may be a signal that controls the operation of the first power transistor to change a slope of a current flowing through an inductor included in the power converter versus time.

### CROSS-REFERENCE

This application claims priority under 35 U.S.C. § 119 to Korean Patent Application No. 10-2024-0030912, filed on Mar. 4, 2024 in the Korean Intellectual Property Office (KIPO), the disclosure of which is incorporated by reference herein in its entirety.

### FIELD

The present disclosure generally relates to power converters, and more specifically relates to a device and method for sensing and compensating an overshoot voltage in a power converter.

### DISCUSSION

Power converters may convert alternating current (AC) to AC, AC to direct current (DC), DC to DC, and/or DC to AC. DC to DC power converters may convert DC power to DC power such as by using a linear regulator, a voltage regulator, a motor-generator, a rotary converter, or a switched-mode power supply.

Due to their high power efficiency, switched-mode power supply types of power converters may be used to generate supply voltages that provide power to various electrical components or loads, and the loads may operate by consuming load currents provided by the power converters.

In order to increase the operational speed and capacity of a load, the load current may be increased and the supply voltage may be decreased for high power efficiency. When a high load current is suddenly supplied, a voltage other than a required supply voltage may occur, which may be referred to as an overshoot voltage. When an overshoot voltage occurs, the power converter might provide a relatively unstable supply voltage to the load. Thus, a device and method capable of compensating the overshoot voltage is desired.

### SUMMARY

The present disclosure provides a device and a method for sensing an overshoot voltage by performing a filtering operation on an output voltage of a power converter, and controlling the sensed overshoot voltage by adjusting a slope of a current flowing through an inductor included in the power converter versus time.

In accordance with an embodiment of the present disclosure, a device comprises a power converter including an inductor, a first power transistor configured to decrease a current flowing through the inductor, a second power transistor configured to increase the current flowing through the inductor, and an output node configured to output an output voltage responsive to the current flowing through the inductor; and an overshoot voltage compensation circuit including an overshoot voltage sensing circuit configured to generate a first comparison voltage by performing a filtering operation on the output voltage, and an overshoot voltage control circuit configured to generate a first control signal for controlling operation of at least one of the first power transistor or the second power transistor based on the first comparison voltage to change a slope of the current flowing through the inductor versus time.

In accordance with an embodiment of the present disclosure, a device comprises a power converter including an inductor, a first power transistor configured to decrease a current flowing through the inductor, a second power transistor configured to increase a current flowing through the inductor, and an output node, wherein the power converter is configured to output, to the output node, an output voltage generated by stepping downing an input voltage; a high-pass filter configured to perform a filtering operation on the output voltage to generate a filtered voltage; a first comparator configured to compare the filtered voltage with a first reference voltage to output a first comparison voltage; and an overshoot voltage control circuit configured to generate a control signal based on the first comparison voltage, wherein the control signal is a signal for controlling the power converter to perform an operation of diverting a current flowing through the inductor.

In accordance with an embodiment of the present disclosure, a method of operating a device including a power converter comprises performing a filtering operation on an output voltage of the power converter; sensing an overshoot voltage by comparing the filtered output voltage generated based on the filtering operation with a reference voltage; and compensating an overshoot voltage sensed through an operation of diverting a current flowing through an inductor included in the power converter, wherein the operation of diverting the current flowing through the inductor is an operation of changing a slope of a current flowing through the inductor versus time during a period in which the magnitude of a current applied to a load device connected to the power converter decreases.

### BRIEF DESCRIPTION OF THE DRAWINGS

In order to better understand the drawings of the present disclosure as described in the detailed description, a brief description of each drawing is provided. Embodiments of the present disclosure will be more clearly understood from the following detailed description when taken in conjunction with the accompanying drawings, in which:

FIG. 1A is a block diagram schematically illustrating a device for compensating an overshoot voltage, according to an embodiment;

FIG. 1B is a graphical diagram for explaining an overshoot voltage;

FIG. 2 is a block diagram illustrating a device including an overshoot voltage compensation circuit, according to an embodiment;

FIG. 3 is a graphical diagram for describing an operation of compensating an overshoot voltage of a device including an overshoot voltage compensation circuit, according to an embodiment;

FIG. 4 is a block diagram illustrating a device including an overshoot voltage compensation circuit, according to an embodiment;

FIG. 5A is a block diagram illustrating a device including an overshoot voltage compensation circuit, according to an embodiment;

FIGS. 5B and 5C are graphical diagrams for explaining operations according to modes of a device including an overshoot voltage compensation circuit, according to an embodiment;

FIG. 6 is a block diagram illustrating a device including an overshoot voltage compensation circuit, according to an embodiment;

FIG. 7A is a block diagram illustrating a device including an overshoot voltage compensation circuit, according to an embodiment;

FIG. 7B is a graphical diagram for describing an operation of compensating an overshoot voltage of a device including an overshoot voltage compensation circuit, according to an embodiment;

FIG. 8 is a block diagram illustrating a device including an overshoot voltage compensation circuit, according to an embodiment;

FIG. 9 is a flowchart diagram illustrating a method for compensating an overshoot voltage, according to an embodiment; and

FIG. 10 is a block diagram illustrating an electronic device according to an embodiment.

### DETAILED DESCRIPTION

Hereinafter, illustrative embodiments of the present disclosure will be described in detail with reference to the accompanying drawings.

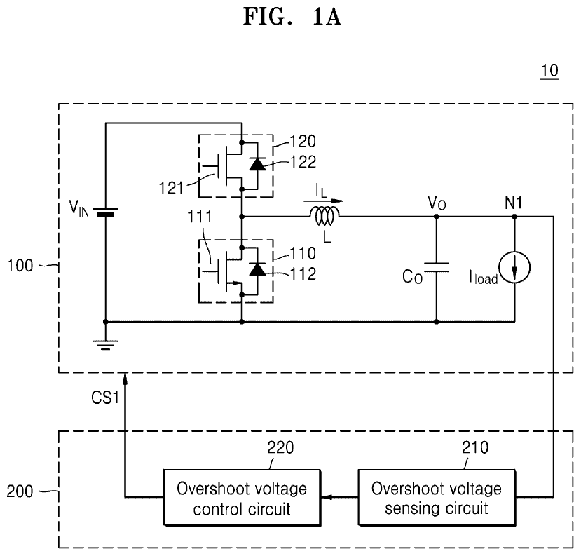

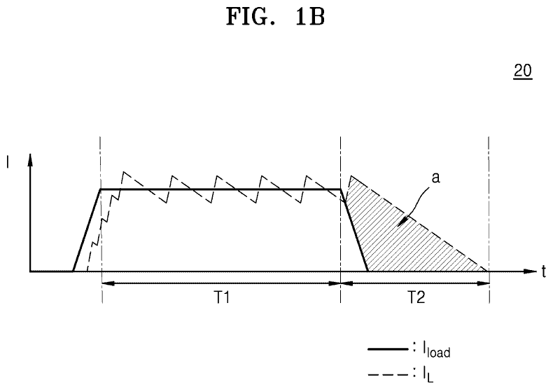

As shown in FIG. 1A, a device for compensating an overshoot voltage according to an embodiment is indicated generally by the reference numeral 10.

As shown in FIG. 1B, an overshoot voltage with respect to a plot of current versus time is indicated generally by the reference numeral 20.

Referring to FIG. 1A, the device 10 may include a power converter 100 and an overshoot voltage compensation circuit 200. The power converter 100 may generate an output voltage Vo based on an input voltage VIN and supply the output voltage Vo generated as a supply voltage to a load through an output node N1. In an embodiment, the power converter 100 may be a buck-converter that lowers the input voltage V_{IN} to supply the lowered output voltage Vo to the load. For example, the power converter 100 may be an adaptive on time (AOT) buck-converter that has relatively fast dynamic characteristics. It shall be understood that the present disclosure is not limited to buck-converters, and may similarly be applied to boost converters, buck-boost converters, switched-mode power supply converters, and/or other types of power converters as presently known or later developed in the pertinent field of art to meet various application criteria.

The power converter 100 may include an inductor L, a first power transistor 110, a second power transistor 120, and an output capacitor Co. The first power transistor 110 and the second power transistor 120 may be configured to increase or decrease via a current I_{L} flowing through the inductor L. For example, the first power transistor 110 may include a first metal-oxide-semiconductor field-effect transistor (MOSFET) 111 and a first diode 112, and when a turn-on operation is performed by receiving a signal (e.g., a high level logic signal) from a gate terminal of the first MOSFET 111, the current I_{L} may be decreased through the inductor L. For example, the second power transistor 120 may include a second MOSFET 121 and a second diode 122, and when a turn-on operation is performed by receiving a signal (e.g., a high level logic signal) from a gate terminal of the second MOSFET 121, the current I_{L} may be increased through the inductor L. The power converter 100 may increase or decrease the current I_{L} through the inductor L and supply the output voltage Vo to the load through the output node N1. A current source I_{load} may denote the load. In an embodiment, the diodes 112 and 122 may be body diodes or the like of MOSFETs 111 and 121, respectively. In an embodiment, the first and second power transistors may include transistors 111 and 121, which need not be bodied MOSFETs, as well as diodes 112 and 122, each implemented separately.

In an embodiment, the load may be a memory device, without limitation thereto. For example, the load may be a dynamic RAM (DRAM). In the following specification, a DRAM load is generally provided as an example, but the present disclosure is not limited thereto. For example, the load may include volatile memory such as static random access memory (SRAM) and/or synchronous DRAM (SDRAM), and/or nonvolatile memory such as phase-change RAM (PRAM), magneto-resistive RAM (MRAM), Resistive RAM (ReRAM), and/or ferro-electric RAM (FRAM).

When the power converter 100 supplies the output voltage Vo to the load, an overshoot voltage may occur. The overshoot voltage may be a voltage greater than the output voltage Vo required by the load, and an overshoot voltage greater than or equal to an error range may cause the power converter 100 to supply a relatively unstable voltage to the load.

Referring further to FIG. 1B, the overshoot voltage 20 is based currents I_{LOAD} and I_{L}, where the horizontal axis may represent time t, and the vertical axis may represent the magnitude of current I. A first period T1 may be a period in which the power converter 100 supplies a constant load current I_{load}, and a second period T2 may be a period in which the load current I_{load} is reduced. In the second period T2, a difference may occur between a speed at which the current I_{L} of the inductor L is decreased and a speed at which the load current I_{load} is decreased and, accordingly, a difference in an amount of charge corresponding to an area of a first region “a” may accumulate in an output capacitor. The amount of increase may be calculated according to the following equation.

$$Δ Q = {C}_{O} \cdot {V}_{0 S} \qquad [ Equation 1 ]$$

ΔQ may be the difference or delta in an amount of charge, Co may be a capacity of an output capacitor Co, and Vos may be an overshoot voltage. Here, as the load current I_{load} drawn by the load increases, the delta increase amount ΔQ may increase. The load and the device 10 may be implemented as one or more integrated circuit chips, and may be mounted on a printed circuit board. In connection with an increase in the operational speed and capacity of the load, the size of the load may be increased, but the size of the printed circuit board may be limited. Accordingly, the size of the device 10 may be limited, and the size of the output capacitor Co need not be increased in order to increase the capacity of the output capacitor Co depending on the limited size. Since the capacity of the output capacitor Co is not increased, the overshoot voltage Vos may increase as the amount of delta increase (ΔQ) is increased. Since the increased overshoot voltage Vos may degrade the performance of the power converter 100, the embodiment of FIG. 1A may be applied without increasing the size of the output capacitor Co, and the overshoot voltage compensation circuit 200 may sense an overshoot voltage Vos and may reduce the sensed overshoot voltage Vos.

In greater detail, the overshoot voltage compensation circuit 200 may include an overshoot voltage sensing circuit 210 and an overshoot voltage control circuit 220.

The overshoot voltage sensing circuit 210 may be connected to the output node N1 of the power converter 100 to receive the output voltage Vo, and may generate a first comparison voltage by performing a filtering operation on the output voltage Vo.

In an embodiment, the overshoot voltage sensing circuit 210 may include a high pass filter and pass only an alternating current component of the output voltage Vo. The overshoot voltage sensing circuit 210 may compare an alternating current (AC) component of the output voltage Vo with a first reference voltage to generate a first comparison voltage. The first reference voltage may be a preset voltage, and may be a voltage within an error range corresponding to an alternating current component of the output voltage Vo. The output voltage Vo may include a ripple voltage for stability, and the magnitude of the direct current (DC) component of the output voltage Vo may be changed by the ripple voltage. Accordingly, when the output voltage Vo is compared with the reference voltage, an error range might be relatively large, and an overshoot voltage might be sensed relatively imprecisely. But since the overshoot voltage sensing circuit 210 generates a first comparison voltage by comparing the alternating current component of the output voltage Vo with the first reference voltage, an error range may be reduced and the overshoot voltage may be sensed relatively precisely. In other words, the overshoot voltage sensing circuit 210 may sense even a relatively low overshoot voltage.

The overshoot voltage control circuit 220 may receive the first comparison voltage from the overshoot voltage sensing circuit 210 and generate a first control signal CS1 for controlling the operation of the first power transistor 110 based on the first comparison voltage.

In an embodiment, the first control signal CS1 may be a signal that controls the operation of the first power transistor 110 to change the slope of the current I_{L} flowing through the inductor L. For example, the power converter 100 may receive a first control signal CS1 from the overshoot voltage control circuit 220 and apply a signal (e.g., a low level logic signal) to the gate terminal of the first MOSFET 111 based on the first control signal CS1. The first MOSFET 111 may be turned off according to a signal applied to a gate terminal, and a current IL may flow through the first diode 112. The current I_{L} may be diverted by the first diode 112, and a slope of the current I_{L} flowing through the inductor L may increase in a negative direction or become downwardly steeper in the second period T2. Accordingly, since the amount of delta increase (ΔQ) may be reduced, the overshoot voltage Vos may be reduced.

Since the overshoot voltage sensing circuit 210 of the overshoot voltage compensation circuit 200 according to an embodiment senses an overshoot voltage based on the alternating current component of the output voltage Vo by performing a filtering operation, a relatively low overshoot voltage may be sensed, and since the overshoot voltage compensation circuit 200 according to an embodiment generates a first control signal CS1 for controlling the first MOSFET 111 to turn off, a current flowing through the inductor through the first diode 112 may be diverted. Accordingly, the overshoot voltage may be reduced without increasing the size of the output capacitor Co. Accordingly, the device 10 may provide a relatively stable supply voltage to a load.

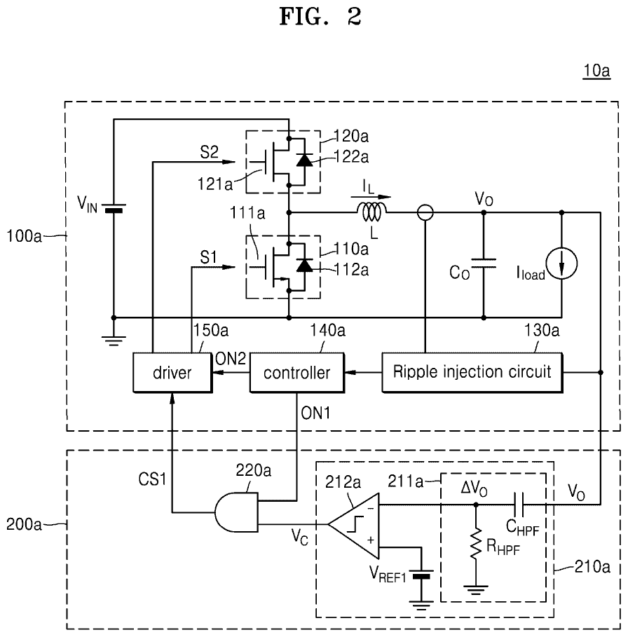

Turning to FIG. 2, a device including an overshoot voltage compensation circuit according to an embodiment is indicated generally by the reference numeral 10a. In an embodiment, a device 10a of FIG. 2 may be an example of the device 10 of FIG. 1A.

Referring to FIGS. 1A and 2, a device 10a may include a power converter 100a and an overshoot voltage compensation circuit 200a. The power converter 100a may include an inductor L, an output capacitor Co, a first power transistor 110a, a second power transistor 120a, a ripple injection circuit 130a, a controller 140a, and a driver 150a. The inductor L, the output capacitor Co, the first power transistor 110a, and the second power transistor 120a may be substantially the same as the inductor L, the output capacitor Co, the first power transistor 110, and the second power transistor 120 of FIG. 1A. Substantially redundant description to the description provided with reference to FIG. 1A may be omitted.

The ripple injection circuit 130a may be a circuit for applying a ripple voltage to the output voltage Vo, such as for stability of the output voltage Vo, and the controller 140a may receive a signal from the ripple injection circuit 130a and generate a signal for controlling the driver 150a. The driver 150a may apply an operational signal S1 or S2 to the first power transistor 110a or the second power transistor 120a based on a signal received from the controller 140a and/or a signal received from the overshoot voltage compensation circuit 200a, such as, for example, based on a signal from a logic gate of the overshoot voltage compensation circuit 200a, without limitation thereto.

The overshoot voltage compensation circuit 200a may include an overshoot voltage sensing circuit 210a and an AND gate 220a. The overshoot voltage sensing circuit 210a may include a high pass filter 211a and a first comparator 212a. In an embodiment, the high pass filter 211a may include a capacitor C_{HPF} and a resistor R_{HPF}, and may receive the output voltage Vo as an input and perform a high pass filtering operation on the output voltage Vo to generate a filtered voltage ΔVₒ. The filtered voltage ΔVₒ may be a voltage including an alternating current component of the output voltage Vo. Although an overshoot voltage compensation circuit embodiment including at least one AND gate is shown and described, embodiments are not limited thereto. For example, in an alternate embodiment, the overshoot voltage compensation circuit may include at least one NOR gate.

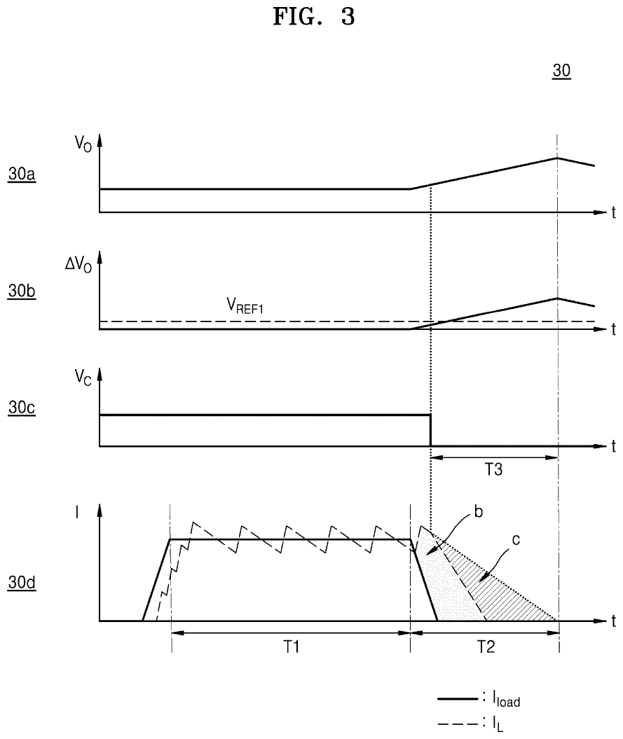

In an embodiment, the first comparator 212a may receive the filtered voltage ΔVₒ and the first reference voltage V_{REF1} as inputs and compare the same with each other to generate a first comparison voltage Vc. For example, when the filtered voltage ΔVₒ is greater than the first reference voltage V_{REF1}, the first comparator 212a may output the first comparison voltage Vc as a low level logic signal (e.g., 0 V voltage) during a period T3 in the signal plot 30c of FIG. 3, infra. For example, when the filtered voltage ΔVₒ is less than the first reference voltage V_{REF1}, the first comparator 212a may output the first comparison voltage Vc as a high level logic signal (e.g., a voltage exceeding 0 V) during a period before T3 overlapping the period T1 and a beginning portion of the period T2 in the signal plots 30c and 30d of FIG. 3, infra.

In an embodiment, the AND gate 220a may be an example of the overshoot voltage control circuit 220 of FIG. 1A. The controller 140a may generate a signal ON1 as an input to the AND gate 220a which outputs a first control signal CS1 as an input to control the driver 150a to output a signal S1 for turning on or off the first power transistor 110a. The AND gate 220a may receive the signal ON1 from the controller 140a and a first comparison voltage Vc from the first comparator 212a, and output a first control signal CS1 based on the result. For example, when both the signal ON1 and the first comparison voltage Vc are a high level logic signal (e.g., voltage exceeding 0 V), the first control signal CS1 of the high level logic signal (e.g., voltage exceeding 0 V) may be output. For example, when at least one of the signal ON1 or the first comparison voltage Vc is a low level logic signal (e.g., 0 V voltage), the first control signal CS1 of a low level logic signal (e.g., 0 V voltage) may be output.

In an embodiment, the driver 150a may apply an operational signal S1 or S2 to the first power transistor 110a or the second power transistor 120a based on a signal ON2 received from the controller 140a or the first control signal CS1 received from the AND gate 220a. The controller 140a may generate a signal ON2 which is applied to the driver 150a which outputs a signal S2 for turning on or off the second power transistor 120a.

For example, when receiving a signal ON2 of a high level logic signal (e.g., a voltage exceeding 0 V) from the controller 140a, the driver 150a may generate a signal S2 of a high level logic signal (e.g., a voltage exceeding 0 V) and apply the signal S2 to the gate terminal of the second MOSFET 121a, and may turn on the second power transistor 120a. For example, when receiving a signal ON2 of a low level logic signal (e.g., a voltage of 0 V) from the controller 140a, the driver 150a may generate a signal S2 of a low level logic signal (e.g., a voltage of 0 V) and apply the signal S2 to the gate terminal of the second MOSFET 121a, and may turn off the second power transistor 120a.

For example, when receiving the first control signal CS1 of a high level logic signal (e.g., a voltage exceeding 0 V) from the AND gate 220a, the driver 150a may generate a signal S1 of a high level logic signal (e.g., a voltage exceeding 0 V) and apply the signal S1 to the gate terminal of the first MOSFET 111a, and may turn on the first power transistor 110a.

For example, when receiving the first control signal CS1 of a low level logic signal (e.g., a voltage of 0 V) from the AND gate 220a, the driver 150a may generate the signal S1 of a low level logic signal (e.g., a voltage of 0 V) and apply the signal S1 to the gate terminal of the first MOSFET 111, and may turn off the first power transistor 110a.

When an overshoot voltage is sensed, the overshoot voltage compensation circuit 200a may control the first power transistor 110a to be turned off by the controller 140a, which does not transmit, to the driver 150a, a signal ON1 generated to turn on the first power transistor 110a and transmit the first control signal CS1 generated to turn off the first power transistor 110a to the driver 150a through the AND gate 220a. Accordingly, since the device 10a may divert the current I_{L} flowing through the inductor L, the overshoot voltage may be reduced without increasing the size of the output capacitor Co. In other words, the device 10a may stably provide a supply voltage to a load.

Turning now to FIG. 3, an operation of compensating an overshoot voltage of a device including an overshoot voltage compensation circuit according to an embodiment is indicated generally by the reference numeral 30.

Referring to FIGS. 2 and 3, a first signal plot 30a shows an output voltage Vo versus time, a second signal plot 30b shows a filtered voltage ΔVₒ versus time, a third signal plot 30c shows a first comparison voltage Vc versus time, and a fourth signal plot 30d shows a reduced overshoot voltage versus time.

A first period T1 and a second period T2 of the signal plot 30d may be substantially the same as the first period T1 and the second period T2 of FIG. 1B, and redundant descriptions are omitted. In the first period T1, the output voltage Vo is constant and the filtered voltage ΔVₒ is also constant with a value less than the first reference voltage V_{REF1}, so the first comparison voltage Vc may be a high level logic signal (e.g., a voltage exceeding 0 V).

In the second period T2, the output voltage Vo increases and the filtered voltage ΔVₒ also increases, so that the filtered voltage may have a value greater than the first reference voltage V_{REF1}, and thus, the first comparison voltage Vc may be a low level logic signal (e.g., 0 V voltage) while the filtered voltage ΔVₒ has a value greater than the first reference voltage V_{REF1}.

In an embodiment, when an overshoot voltage is sensed (e.g., in the second period T2), the overshoot voltage compensation circuit 200a may control the first power transistor 110a to be turned off by transmitting the first control signal CS1 generated to turn off the first power transistor 110a to the driver 150a through the AND gate 220a, without transmitting, to the driver 150a, a signal ON1 generated to turn on the first power transistor 110a. When the first power transistor 110a is turned off, the device 10a may divert the current IL flowing through the inductor L because a current flows through the first diode 112a.

For example, in the second period T2, the slope of the current I_{L} flowing through the inductor L may have a greater value in a negative direction than the slope of the current I_{L} flowing through the inductor L when the first power transistor 110a is turned on, and may have a smaller area of the second region “b” than the area of the first region “a” of FIG. 1B. In other words, the amount of increase (ΔQ) corresponding to the area of the third region “c” may be reduced based on Equation 1 described with reference to FIG. 1B. Accordingly, the overshoot voltage may be reduced without increasing the size of the output capacitor Co, so that the device 10a may stably provide a supply voltage to the load.

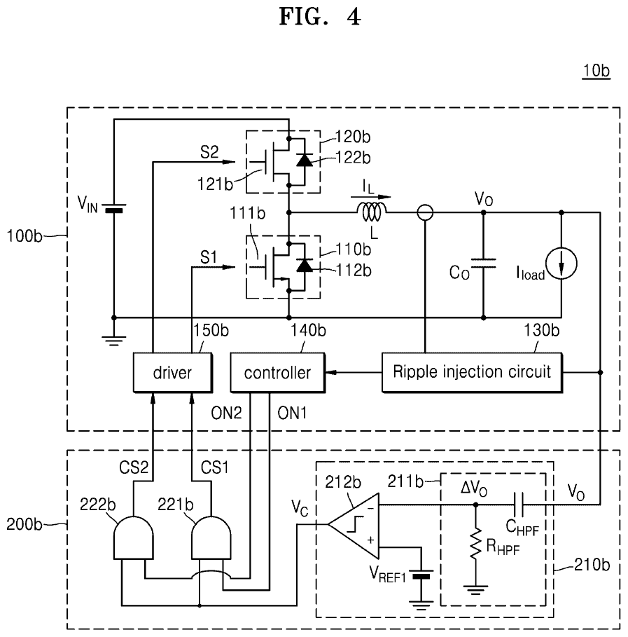

As shown in FIG. 4, a device including an overshoot voltage compensation circuit according to an embodiment is indicated generally by the reference numeral 10b. In an embodiment, a device 10b of FIG. 4 may be an example of the device 10a of FIG. 2.

Referring to FIGS. 2 and 4, a device 10b may include a power converter 100b and an overshoot voltage compensation circuit 200b. The power converter 100b may include an inductor L, an output capacitor Co, a first power transistor 110b, a second power transistor 120b, a ripple injection circuit 130b, a controller 140b, and a driver 150b. The inductor L, the output capacitor Co, the first power transistor 110b, the second power transistor 120b, and the ripple injection circuit 130b of FIG. 4 may be substantially the same as the inductor L, the output capacitor Co, the first power transistor 110a, the second power transistor 120a, and the ripple injection circuit 130a of FIG. 2, and a redundant description with that provided with reference to FIG. 2 may be omitted.

The controller 140b may generate a signal ON1 or ON2 for controlling the first power transistor 110b or the second power transistor 120b to be turned on or off.

The overshoot voltage compensation circuit 200b may include an overshoot voltage sensing circuit 210b, a first AND gate 221b, and a second AND gate 222b, and the overshoot voltage sensing circuit 210b may include a high pass filter 211b and a first comparator 212b. The high pass filter 211b and the first comparator 212b of FIG. 4 may be substantially the same as the high pass filter 211a and the first comparator 212a of FIG. 2, and a redundant description with that provided with reference to FIG. 2 may be omitted.

In an embodiment, the first AND gate 221b and the second AND gate 222b of FIG. 4 may be examples of the overshoot voltage control circuit 220 of FIG. 1A. The first AND gate 221b of FIG. 4 may be substantially the same as the AND gate 220a of FIG. 2, and a redundant description with that provided with reference to FIG. 2 may be omitted.

In an embodiment, the second AND gate 222b may receive a signal ON2 from the controller 140b and a first comparison voltage Vc from the first comparator 212a, and output a second control signal CS2 based on the same. For example, when both the signal ON2 and the first comparison voltage Vc are a high level logic signal (e.g., voltage exceeding 0 V), the second control signal CS2 of the high level logic signal (e.g., voltage exceeding 0 V) may be output. For example, when at least one of the signal ON2 or the first comparison voltage Vc is a low level logic signal (e.g., 0 V voltage), the second control signal CS2 of a low level logic signal (e.g., 0 V voltage) may be output.

In an embodiment, the driver 150b may receive the control signals (e.g., CS1 and CS2) from the first AND gate 221b and the second AND gate 222b, and based on this, an operational signal S1 or S2 may be applied to the first power transistor 110b or the second power transistor 120b. The operation of the driver 150c according to the first control signal may be substantially the same as the operation of the driver 150a described with reference to FIG. 2, and redundant descriptions with those provided with reference to FIG. 2 are omitted.

For example, when receiving the second control signal CS2 of a high level logic signal (e.g., a voltage exceeding 0 V) from the second AND gate 220b, the driver 150b may generate a signal S2 of a high level logic signal (e.g., a voltage exceeding 0 V) and apply the signal S2 to the gate terminal of the second MOSFET 121b, and may turn on the second power transistor 120b.

For example, when receiving the second control signal CS2 of a low level logic signal (e.g., a voltage of 0 V) from the second AND gate 222b, the driver 150b may generate the signal S2 of a low level logic signal (e.g., a voltage of 0 V) and apply the signal S2 to the gate terminal of the second MOSFET 121b, and may turn off the second power transistor 120b.

When an overshoot voltage is sensed, the overshoot voltage compensation circuit 200b may control the first power transistor 110b to be turned off by the controller 140b, which does not transmit, to the driver 150b, a signal ON2 generated to turn on the second power transistor 120b and transmit the second control signal CS2 generated to turn off the second power transistor 120b to the driver 150b through the second AND gate 222b. Accordingly, the current IL of the inductor L may be prevented from being increased due to the input voltage V_{IN}.

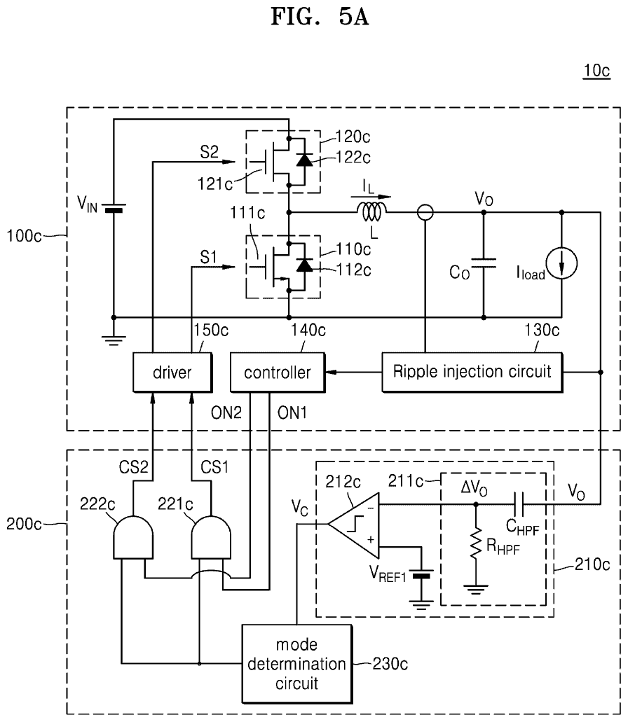

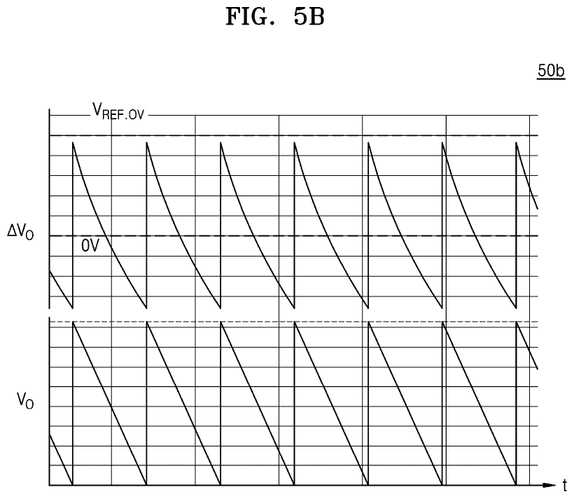

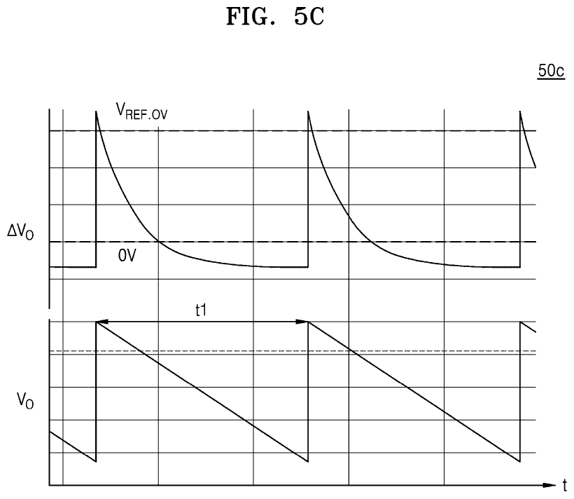

Turning to FIG. 5A, a device including an overshoot voltage compensation circuit according to an embodiment is indicated generally by the reference numeral 10c. Turning to FIGS. 5B and 5C, operations according to modes of a device including an overshoot voltage compensation circuit are indicated generally by the reference numerals 50b and 50c, respectively. In an embodiment, a device 10c of FIG. 5A may be an example of the device 10b of FIG. 4.

Referring to FIGS. 4 and 5A, a device 10c may include a power converter 100c and an overshoot voltage compensation circuit 200c. The power converter 100c may be substantially the same as the power converter 100b of FIG. 4, and a redundant description with that provided with reference to FIG. 4 may be omitted. The overshoot voltage compensation circuit 200c of FIG. 5A may be a circuit in which a mode determination circuit 230c is added to the overshoot voltage compensation circuit 200b of FIG. 4, and a redundant description with that provided with reference to FIG. 4 may be omitted.

In an embodiment, the power converter 100c may operate in either a discontinuous current mode (DCM) or a continuous current mode (CCM). For example, the first power transistor 110c and the second power transistor 120c may be alternately turned on or off, and in this case, when the load current I_{load} is greater than half of the change amount of the current I_{L} flowing through the inductor L of the power converter 100c compared with the load current I_{load}, the power converter 100c may operate in a DCM, and when the load current I_{load} is less than half of the change amount of the current I_{L}, the power converter 100c may operate in a CCM.

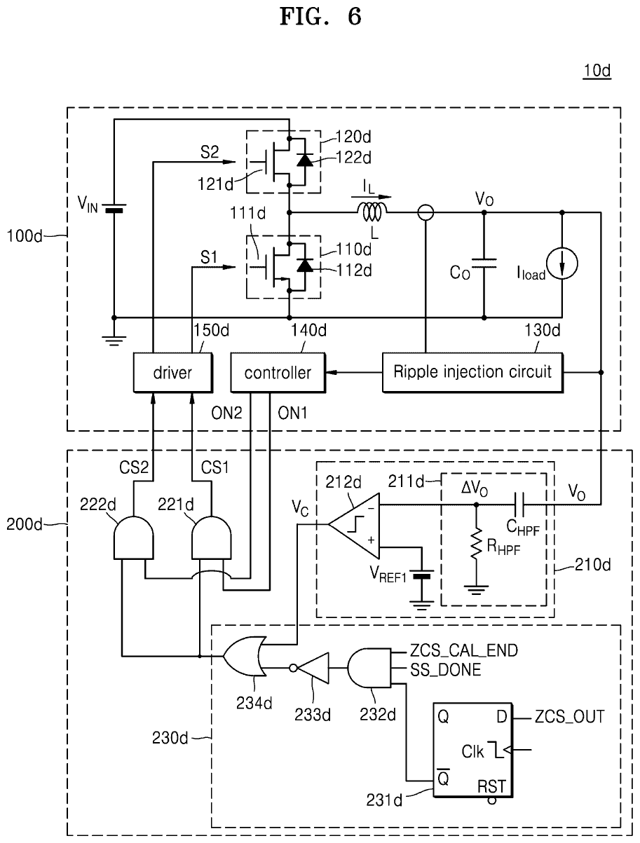

The mode determination circuit 230c may determine whether the power converter 100c operates in either a DCM or a CCM. Configuration and operation of the mode determination circuit 230c may be described in greater detail further below with reference to FIG. 6.

In an embodiment, the overshoot voltage compensation circuit 200c may perform an overshoot voltage reduction operation according to a mode determined by the mode determination circuit 230c. The overshoot voltage reduction operation may be an operation of generating a signal for controlling the operation of the first power transistor 110c to change the slope of the current I_{L} flowing through the inductor L.

For example, the overshoot voltage compensation circuit 200c may perform an overshoot voltage reduction operation on the sensed overshoot voltage when the mode determination circuit 230c determines the mode of the power converter 100c as a CCM.

For example, the overshoot voltage compensation circuit 200c may not perform an overshoot voltage reduction operation on the sensed overshoot voltage when the mode determination circuit 230c determines the mode of the power converter 100c as a DCM.

Referring further to FIGS. 5B and 5C, a signal plot 50b and a signal plot 50c show the output voltage Vo and the filtered voltage ΔVₒ versus time when the power converter 100c operates in a DCM. The vertical axes of the signal plot 50b and the signal plot 50c may represent the magnitude of a voltage, and the horizontal axes may represent time t. When the power converter 100c operates in a DCM, the frequency of the output voltage Vo may decrease as the load current I_{load} decreases, and accordingly, distortion may occur in the filtered voltage ΔVₒ. Distortion of the filtered voltage ΔVₒ may be prevented by adjusting the capacitor C_{HPF} and the resistor R_{HPF} included in the overshoot voltage sensing circuit 210c, but when the load current I_{load} is less than or equal to a threshold current, distortion may occur in the filtered voltage ΔVₒ even when the capacitor C_{HPF} and the resistor R_{HPF} included in the overshoot voltage sensing circuit 210c are adjusted. The threshold current may refer to a current at which distortion of the filtered voltage ΔVₒ occurs.

For example, the load current I_{load} in the signal plot 50b may be greater than a threshold current, and distortion of the filtered voltage ΔVₒ may be prevented by adjusting the capacitor C_{HPF} and the resistor R_{HPF} included in the overshoot voltage sensing circuit 210c in the signal plot 50b. The filtered voltage ΔVₒ may have a constant amplitude based on 0 V, and the overshoot voltage compensation circuit 200c may sense the overshoot voltage based on a constant reference voltage V_{REF.0V}.

For example, the load current I_{load} in the signal plot 50c may be less than or equal to the threshold current, and in the section t1, distortion occurs in the voltage ΔVₒ filtered to the low-frequency region and may not have a constant amplitude based on 0 V. Accordingly, the overshoot voltage compensation circuit 200c may sense an overshoot voltage based on the relatively high reference voltage V _{REF.0v}, and when the overshoot voltage is sensed based on the high reference voltage V_{REF.0v}, the overshoot voltage improvement effect may be relatively reduced.

The overshoot voltage compensation circuit 200c may not perform an overshoot voltage reduction operation when the power converter 100c operates in a DCM, and may perform an overshoot voltage reduction operation when the power converter 100c operates in a CCM, thereby improving the overshoot voltage improvement effect.

Turning now to FIG. 6, a device including an overshoot voltage compensation circuit according to an embodiment is indicated generally by the reference numeral 10d. In an embodiment, a device 10d of FIG. 6 may be an example of the device 10c of FIG. 5A. Substantially redundant description to that provided with reference to FIG. 5A may be omitted.

Referring to FIG. 6, a mode determination circuit 230d may include a flip-flop 231d, a third AND gate 232d, an inverter 233d, and an OR gate 234d. In an embodiment, the flip-flop 231d may receive a first signal ZCS_OUT as an input, and may receive, as a clock signal CLK, a signal ON2 from a controller 140d. The first signal ZCS_OUT may have a high level logic signal (e.g., a voltage exceeding 0 V) when the magnitude of the current is less than or equal to 0, and may have a low level logic signal (e.g., a voltage of 0 V) when the magnitude of the current exceeds 0.

For example, the first signal ZCS_OUT may be generated on the basis of the current I_{L} flowing through the inductor L, and the flip-flop 231d may generate an output signal of a low level logic signal (e.g., 0 V voltage) when the power converter 100d operates in a DCM, and may generate an output signal of a high level logic signal (e.g., a voltage exceeding 0 V) when the power converter 100d operates in a CCM.

In an embodiment, the third AND gate 232d may receive, as inputs, a second signal ZCS_CAL_END, a third signal SS_DONE, and the output signal of the flip-flop 231d. The second signal ZCS_CAL_END and the third signal SS_DONE may be signals indicating a time point at which the power converter 100d normally operates. For example, the second signal ZCS_CAL_END may be a high level logic signal (e.g., a voltage exceeding 0 V) when the calibration for a circuit (not shown) generating the first signal ZCS_OUT is completed, and the third signal SS_DONE may be a high level logic signal (e.g., a voltage exceeding 0 V) when the power of the device 10d is turned on.

In an embodiment, the inverter 233d may invert the output of the third AND gate 232d. In an embodiment, the OR gate 234d may receive the output of the inverter 233d and the first comparison voltage Vc as inputs, and the first AND gate 221d and the second AND gate 222d may receive the output of the OR gate 234d as an input.

For example, when the power converter 100d operates in a DCM, the output of the third AND gate 232d is a low level logic signal (e.g., 0 V), and thus, the OR gate 234d may generate an output of a high level logic signal (e.g., a voltage exceeding 0 V) regardless of the first comparison voltage Vc. Accordingly, since the signal ON1 or ON2 generated by the controller 140d may be transmitted to the driver 150d, the overshoot voltage compensation circuit 200d may not perform the overshoot voltage reduction operation.

For example, when the power converter 100d operates in a CCM, the output of the third AND gate 232d is a high level logic signal (e.g., a voltage exceeding 0 V), and thus, the OR gate 234d may generate an output of a high level logic signal (e.g., a voltage exceeding 0 V) or a low level logic signal (e.g., a voltage of 0 V) according to the first comparison voltage Vc. In other words, the overshoot voltage compensation circuit 200d may perform an overshoot voltage reduction operation on the sensed overshoot voltage.

The overshoot voltage compensation circuit 200d may not perform an overshoot voltage reduction operation when the power converter 100d operates in a DCM, and may perform an overshoot voltage reduction operation when the power converter 100d operates in a CCM, thereby improving the overshoot voltage improvement effect.

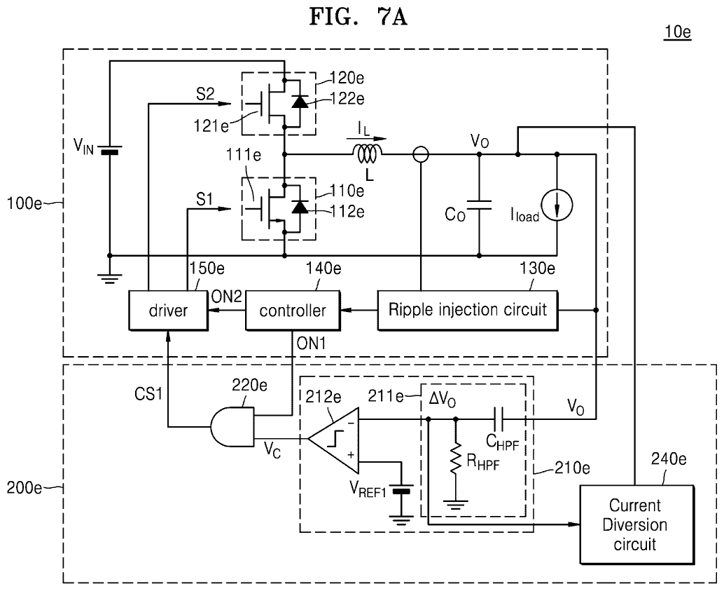

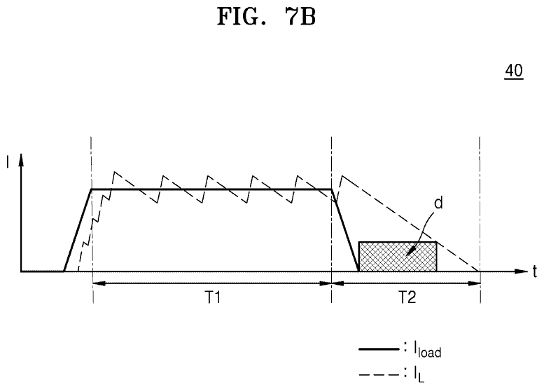

As shown in FIG. 7A, a device including an overshoot voltage compensation circuit according to an embodiment is indicated generally by the reference numeral 10e.

As shown in FIG. 7B, a signal plot for an operation of compensating an overshoot voltage of a device including an overshoot voltage compensation circuit according to an embodiment is indicated generally by the reference numeral 40.

In an embodiment, a device 10e of FIG. 7A may be an example of the device 10a of FIG. 2. Substantially redundant description to that provided with reference to FIGS. 2 and/or 3 may be omitted.

Referring to FIGS. 2 and 7A, a device 10e may include a power converter 100e and an overshoot voltage compensation circuit 200e. The power converter 100e may be substantially the same as the power converter 100a of FIG. 2, and substantially redundant description to that provided with reference to FIG. 2 may be omitted. The overshoot voltage compensation circuit 200e of FIG. 7A may be a circuit in which a current diversion circuit 240e is added to the overshoot voltage compensation circuit 200a of FIG. 2, and as described with reference to FIG. 2, the overshoot voltage may be sensed and the sensed overshoot voltage may be reduced. For example, the overshoot voltage sensing circuit 210e may sense an overshoot voltage relatively precisely by comparing the alternating current component of the output voltage Vo with the first reference voltage V_{REF1}, to thereby generate a first comparison voltage, and when the overshoot voltage sensing circuit 210e senses the overshoot voltage, the overshoot voltage control circuit 220e may generate a first control signal CS1 that controls the first MOSFET 111e to be turned off. Hereinafter, substantially redundant descriptions to those provided with reference to FIG. 2 are omitted.

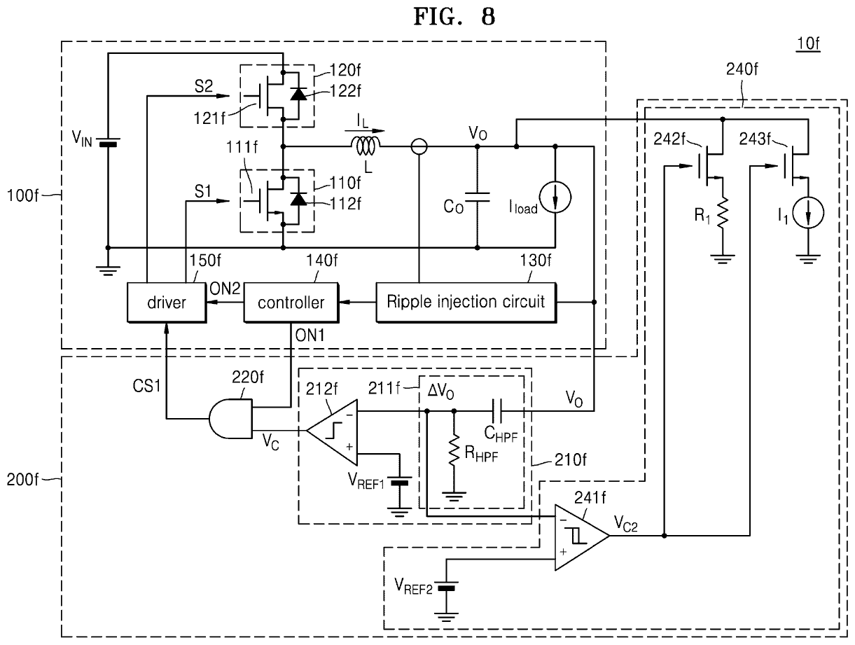

In an embodiment, the current diversion circuit 240e may perform an operation of diverting the current I_{L} flowing through the inductor L based on the filtered voltage ΔVₒ. For example, the current diversion circuit 240e may compare the filtered voltage ΔVₒ with a second reference voltage to generate a second comparison voltage, and may perform an operation of diverting the current I_{L} flowing through the inductor L based on the second comparison voltage. The specific structure and operation of the current diversion circuit 240e may be described in greater detail further below with reference to FIG. 8.

Referring further to FIG. 7B, the horizontal axis of the signal plot may represent time t, and the vertical axis may represent a magnitude of current I. A first period T1 and a second period T2 of FIG. 7B may be substantially the same as the first period T1 and the second period T2 of FIG. 1B, and redundant descriptions are omitted. When sensing an overshoot voltage (e.g., in the second period T2), the current diversion circuit 240e may perform an operation of diverting the current I_{L} flowing through the inductor L, and accordingly, the amount of delta increase (ΔQ) may also be reduced, so that the amount of increase corresponding to a fourth region “d” may be reduced from the first region “a” of FIG. 1B. In other words, the current diversion circuit 240e may reduce an overshoot voltage sensed by diverting the current I_{L} flowing through the inductor L without increasing the size of the output capacitor Co included in the power converter 100e.

Turning to FIG. 8, a device including an overshoot voltage compensation circuit according to an embodiment is indicated generally by the reference numeral 10f. In an embodiment, a device 10f of FIG. 8 may be an example of the device 10e of FIG. 7A. Substantially redundant description to that provided with reference to FIG. 7A may be omitted.

Referring to FIG. 8, a current diversion circuit 240f may be an example of the current diversion circuit 240e of FIG. 7A, and the current diversion circuit 240f may include a second comparator 241f, a first transistor 242f, a resistor R₁, a second transistor 243f, and a current source I₁. Although the current diversion circuit 240f includes all of the second comparator 241f, the first transistor 242f, the resistor R₁, the second transistor 243f, and the current source I₁, embodiments are not limited thereto. For example, the current diversion circuit 240f may include the second comparator 241f, the first transistor 242f, and the resistor R₁, or may include the second comparator 241f, the second transistor 243f, and a current source I₁.

In an embodiment, the second comparator 241f may compare the filtered voltage ΔVₒ with the second reference voltage V_{REF2} to generate a second comparison voltage Vc2. The second reference voltage V_{REF2} may be a preset voltage. For example, when the filtered voltage ΔVₒ is greater than the second reference voltage V_{REF2}, the second comparator 241f may determine that the overshoot voltage exists and may generate an output of a high level logic signal (e.g., a voltage exceeding 0 V). For example, when the filtered voltage ΔVₒ is less than the second reference voltage V_{REF2}, the second comparator 241f may determine that the overshoot voltage does not exists and may generate an output of a low level logic signal (e.g., a voltage of 0 V).

In an embodiment, the first transistor 242f or the second transistor 243f may receive the output of the second comparator 241f through a gate terminal, and may perform a turn-on operation or a turn-off operation based on the same.

For example, when the first transistor 242f receives a signal of a high level logic signal (e.g., a voltage exceeding 0 V) at the gate terminal, an overshoot voltage is sensed, and thus, a turn-on operation may be performed and the current I_{L} flowing through the inductor L through the resistor R₁ may be diverted.

For example, when the second transistor 243f receives a signal of a high level logic signal (e.g., a voltage exceeding 0 V) at the gate terminal, an overshoot voltage is sensed, and thus, a turn-on operation may be performed and the current I_{L} flowing through the inductor L through the current source I₁ may be diverted.

When the overshoot voltage is sensed, the overshoot voltage compensation circuit 200f may turn on the first transistor 242f or the second transistor 243f to divert the current I_{L} flowing through the resistor R₁ or the current source I₁, thereby reducing the overshoot voltage without increasing the size of the output capacitor Co.

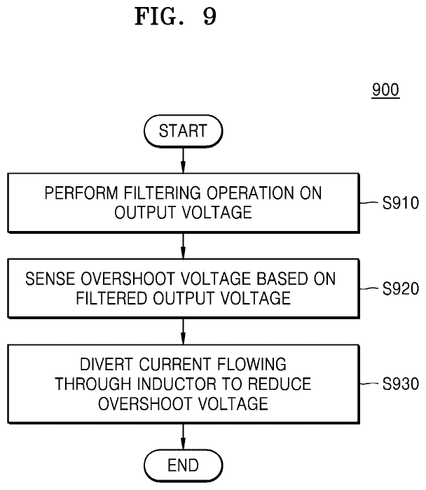

Turning now to FIG. 9, a method for compensating an overshoot voltage according to an embodiment is indicated generally by the reference numeral 900. Referring to FIG. 9, a method 900 of compensating an overshoot voltage may include a plurality of operations S910 to S930.

Referring to FIGS. 1A and 9, in operation S910, the overshoot voltage sensing circuit 210 may perform a filtering operation on an output voltage Vo. In an embodiment, the overshoot voltage sensing circuit 210 may include a high pass filter and may perform a filtering operation of passing only an alternating current component of the output voltage Vo. The output voltage Vo may include a ripple voltage for stability, and the magnitude of the direct current component of the output voltage Vo may be changed by the ripple voltage. Accordingly, when the output voltage Vo is compared with the reference voltage, an error range may be relatively large, and an overshoot voltage may not be sensed relatively precisely. In the case of the filtered voltage, the direct current component may be removed to have a relatively less value compared to the output voltage Vo, and thus the error range may be relatively narrow.

In operation S920, the overshoot voltage sensing circuit 210 may sense the overshoot voltage based on the filtered output voltage. In an embodiment, the overshoot voltage sensing circuit 210 may compare a filtered output voltage with a first reference voltage V_{REF1} to generate a first comparison voltage. The first reference voltage V_{REF1} may be a preset voltage, and may be a voltage within an error range corresponding to an alternating current component of the output voltage Vo. Since the filtered output voltage may have a relatively less value compared to the output voltage Vo, the overshoot voltage may be sensed based on the relatively less first reference voltage V_{REF1}. For example, when the filtered output voltage is greater than the first reference voltage V_{REF1}, the overshoot voltage sensing circuit 210 may sense that the output voltage Vo includes an overshoot voltage. For example, when the filtered output voltage is less than the first reference voltage V_{REF1}, the overshoot voltage sensing circuit 210 may sense that the output voltage Vo does not include an overshoot voltage.

In operation S930, the overshoot voltage control circuit 220 may reduce the sensed overshoot voltage by diverting a current flowing through the inductor. In an embodiment, when the overshoot voltage sensing circuit 210 senses the overshoot voltage, the overshoot voltage control circuit 220 may generate a first control signal CS1 for controlling the operation of the first power transistor 110 to divert the current I_{L} flowing through the inductor L.

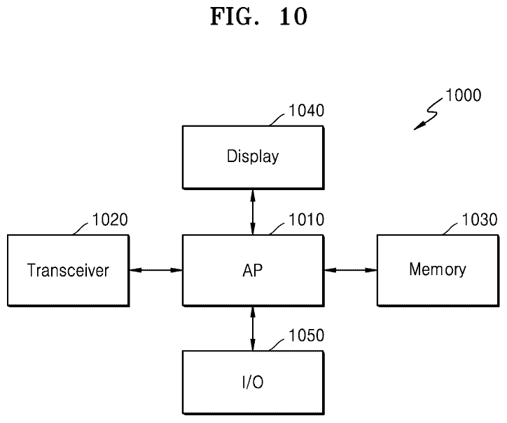

As shown in FIG. 10 is a block diagram illustrating an electronic device according to an embodiment.

Referring to FIG. 10, an electronic device is indicated generally by the reference numeral 1000. The electronic device 1000 may include an application processor (AP) 1010, a transceiver 1020, a memory 1030, a display 1040, and an input/output (I/O) device 1050.

The AP 1010 may control the overall operation of the electronic device 1000 and the operation of the components of the electronic device 1000. The AP 1010 may perform various operations. According to an embodiment, the AP 1010 may include a single processor core or a plurality of processor cores (i.e., a multi-core).

The electronic device 1000 may communicate with the outside through the transceiver 1020. The transceiver 1020 may be, for example, a wireless short-range communication interface, such as a wired local area network (LAN), Bluetooth, Wireless Fidelity (Wi-fi), and Zigbee, or a modem communication interface capable of accessing a mobile cellular network, such as Power Line Communication (PLC), 3rd Generation (3G), Long Term Evolution (LTE), 5G, NR, and next-generation communication.

The memory 1030 may store an instruction code, control data, or user data for controlling the electronic device 1000. The memory 1030 may include at least one of a volatile memory and a nonvolatile memory.

The display 1040 may display internal state information of the electronic device 1000. The display 1040 may include a touch sensor (not shown). In addition, the display 1040 may include input or output functions and external appearances for a user interface. The user may control the electronic device 1000 through the touch sensor and the user interface.

The I/O device 1050 may include input means such as a touch pad, a keypad, an input button, and the like, and output means such as a display, a speaker, and the like.

At least some of the components of the electronic device 1000, for example, the AP 1010, the transceiver 1020, the memory 1030, the display 1040, and the I/O device 1050 may include an overshoot voltage compensation circuit that performs a filtering operation to sense an overshoot voltage and performs an operation of reducing the sensed overshoot voltage. The overshoot voltage compensation circuit 200 according to the embodiments described above with reference to FIGS. 1A to 9 may be applied as the circuit. In an embodiment, an overshoot voltage compensation circuit may be applied to at least one of the AP 1010, the transceiver 1020, the memory 1030, the display 1040, and/or the I/O device 1050. In an embodiment, a plurality of overshoot voltage compensation circuits may be applied to a plurality of the AP 1010, the transceiver 1020, the memory 1030, the display 1040, and/or the I/O device 1050

While the inventive concept has been particularly shown and described with reference to embodiments thereof, it shall be understood by those of ordinary skill in the pertinent art that various changes in form and details may be made therein without departing from the scope and spirit of the present disclosure as set forth in the following claims.

What is claimed is:

1. A device comprising:
a power converter including an inductor, a first power transistor configured to decrease a current flowing through the inductor, a second power transistor configured to increase the current flowing through the inductor, and an output node configured to output an output voltage responsive to the current flowing through the inductor; and
an overshoot voltage compensation circuit including an overshoot voltage sensing circuit configured to generate a first comparison voltage by performing a filtering operation on the output voltage, and an overshoot voltage control circuit configured to generate a first control signal for controlling operation of at least one of the first power transistor or the second power transistor based on the first comparison voltage to change a slope of the current flowing through the inductor versus time.

2. The device of claim 1, wherein the overshoot voltage compensation circuit comprises:
a high-pass filter that includes a capacitor and a resistor and is configured to perform a filtering operation on the output voltage to generate a filtered voltage; and
a first comparator configured to generate the first comparison voltage by comparing the filtered voltage with a first reference voltage,
wherein the power converter is configured to output, to the output node, an output voltage generated by stepping down an input voltage.

3. The device of claim 1,
wherein the first power transistor comprises a first metal oxide semiconductor field effect transistor (MOSFET) having a first diode connected between its source and drain terminals,
wherein the overshoot voltage control circuit generates the first control signal to apply a low level logic signal to a gate terminal of the first MOSFET when the first comparison voltage is a low level logic signal.

4. The device of claim 3,
wherein the power converter further comprises:
a driver that applies a low level logic or a high level logic operational signal to the gate terminal of the first MOSFET; and
a controller configured to generate a signal for controlling the driver,
wherein the overshoot voltage control circuit comprises a logic gate configured to receive the signal from the controller and the first comparison voltage as inputs and to output the first control signal to the driver.

5. The device of claim 3,
wherein the logic gate comprises an AND gate or a NOR gate,
wherein the overshoot voltage control circuit generates a second control signal for controlling the operation of the second power transistor so that the second power transistor is turned off, when the first comparison voltage is a low level logic signal.

6. The device of claim 1,
wherein the power converter operates in either a discrete current mode (DCM) or a continuous current mode (CCM),
wherein the overshoot voltage compensation circuit further comprises a mode determination circuit configured to determine whether the power converter operates in the DCM or the CCM,
wherein the overshoot voltage control circuit generates the first control signal when the mode determination circuit determines the mode of the power converter as the CCM.

7. The device of claim 6,
wherein the power converter further comprises:
a driver for applying a low level logic signal or a high level logic signal to the second power transistor; and
a controller configured to generate a signal for controlling the driver,
wherein the mode determination circuit comprises:
a flip-flop receiving the generated signal from the controller as a clock signal;
an AND gate receiving the output of the flip-flop as an input;
an inverter that receives the output of the AND gate as an input; and
an OR gate receiving the output of the inverter and the first comparison voltage as inputs.

8. The device of claim 1, wherein the overshoot voltage compensation circuit further comprises:
a second comparator generating a second comparison voltage by comparing, with a second reference voltage, the voltage on which the filtering operation on the output voltage received from the overshoot voltage sensing circuit is performed; and
a current diversion circuit configured to divert a current flowing through the inductor, based on the second comparison voltage.

9. The device of claim 8,
wherein the current diversion circuit comprises a first transistor and a resistor, or a second transistor and a current source,
wherein the first transistor or the second transistor performs a turn-on operation based on the second comparison voltage to divert the current flowing through the inductor.

10. The device of claim 1, wherein the overshoot voltage control circuit generates the first control signal during a period in which the magnitude of the current applied to a load device connected to the output node decreases.

11. A device comprising:
a power converter including an inductor, a first power transistor configured to decrease a current flowing through the inductor, a second power transistor configured to increase a current flowing through the inductor, and an output node, wherein the power converter is configured to output, to the output node, an output voltage generated by stepping downing an input voltage;
a high-pass filter configured to perform a filtering operation on the output voltage to generate a filtered voltage;
a first comparator configured to compare the filtered voltage with a first reference voltage to output a first comparison voltage; and
an overshoot voltage control circuit configured to generate a control signal based on the first comparison voltage,
wherein the control signal is a signal for controlling the power converter to perform an operation of diverting a current flowing through the inductor.

12. The device of claim 11,
wherein the first power transistor comprises a MOSFET and a first diode,
wherein the operation of diverting the current flowing through the inductor comprises an operation of turning off the first MOSFET by applying a low level logic signal to the gate terminal of the first MOSFET based on the control signal.

13. The device of claim 12, wherein the operation of diverting the current flowing through the inductor further comprises an operation of turning off the second power transistor based on the control signal.

14. The device of claim 11, further comprising:
a mode determination circuit determining whether the power converter operates in either a DCM or a CCM,
wherein the overshoot voltage control circuit generates the control signal when the mode determination circuit determines the mode of the power converter as the CCM.

15. The device of claim 11, further comprising:
a second comparator configured to compare the filtered voltage with a second reference voltage to output a second comparison voltage; and
a current diversion circuit configured to divert a current flowing through the inductor based on the second comparison voltage.

16. The device of claim 11, wherein the overshoot voltage control circuit generates the control signal during a period in which the magnitude of the current applied to a load device connected to the output node decreases.

17. A method of operating a device including a power converter, the method comprising:
performing a filtering operation on an output voltage of the power converter;
sensing an overshoot voltage by comparing the filtered output voltage generated based on the filtering operation with a reference voltage; and
compensating an overshoot voltage sensed through an operation of diverting a current flowing through an inductor included in the power converter,
wherein the operation of diverting the current flowing through the inductor is an operation of changing a slope of a current flowing through the inductor versus time during a period in which the magnitude of a current applied to a load device connected to the power converter decreases.

18. The method of claim 17,
wherein the power converter comprises: a first power transistor configured to decrease a current flowing through the inductor; and a second power transistor configured to increase a current flowing through the inductor,
wherein the first power transistor comprises a first MOSFET and a first diode, and the reducing of the sensed overshoot voltage comprises turning off the first MOSFET by applying a low level logic signal to the gate terminal of the first MOSFET, and
wherein the operation of diverting the current flowing through the inductor comprises an operation of diverting a current flowing through the inductor by using the first diode.

19. The method of claim 18, wherein the reducing of the sensed overshoot voltage further comprises applying a low level logic signal to the second power transistor to turn off the second power transistor.

20. The method of claim 17, wherein the reducing of the sensed overshoot voltage comprises
determining whether the power converter operates in either a DCM or a CCM, and
performing the operation of diverting the current flowing through the inductor, when the operation mode of the power converter is determined to be the CCM.
